(19) United States
(12) Patent Application Publication
(10) Pub. No.: US 2008/0265445 A1
(43) Pub. Date: Oct. 30, 2008

(54) Marks for the Alignment of Wafer-Level Underfilled Silicon Chips and Method to Produce Same

(75) Inventors: Claudius Feger, Poughkeepsie, NY (US); Nancy LaBianca, Yatesville, CT (US)

Correspondence Address: NUGENT & SMITH, LLP, 91 FOREST BOULEVARD, SUITE 100, ARDSLEY, NY, 10502, US

(73) Assignee: INTERNATIONAL BUSINESS MACHINES CORPORATION, ARMONK, NY (US)

(21) Appl. No.: 11/742,200

(22) Filed: Apr. 30, 2007

(51) Int. Cl. H01L 21/58; H01L 23/544

(52) U.S. Cl. 257/797; 438/113; 257/E23.179; 257/E21.503

(57) ABSTRACT

A semiconductor wafer and the process for aligning wafer level underfill material coated chips with a substrate via alignment marks made visible through laser dicing.

### FIELD OF THE INVENTION

This invention relates to wafer-level underfilled silicon chips.

### BACKGROUND OF THE INVENTION

Flip chip technology is the fastest growing chip interconnect technology as it allows very large numbers of I/Os. Thus, the footprint of chips with low numbers of I/O's can be made very small. This is also true for associated packages such as chip-scale packages.

The major advantage of flip chip technology is that it can utilize the total chip area to make the I/O connections, while wire bonding uses only the chip periphery. A disadvantage of flip chip technology is that stresses that arise from the thermal mismatch between the silicon (chip) thermal expansion coefficient (CTE) and the CTE of the substrate are borne fully by the solder bumps used to make the interconnect between chip and substrate. In order to ameliorate said stresses flip chip packages are usually underfilled, i.e., a resin is placed between the chip and the substrate and acts as encapsulant of the solder bumps and an adhesive between chip and substrate. The effect of such underfills is that the long-time reliability of underfilled flip chip packages is greatly enhanced compared to not underfilled counterparts.

Such resin underfills can be applied by capillary flow, using a no-flow process or by wafer-level applied processes. There are several wafer-level applied underfill processes, among them the Wafer-level Underfill (WLUF) process which uses an over-bump wafer-applied resin, that is then b-staged, followed by dicing the wafer to singulate chips and finally joining the chips with the WLUF layer to substrates. The WLUF process has been described by Feger et al. (U.S. Pat. No. 6,919,420).

However, a WLUF resin material layer can obscure the solder bump pattern and other alignment marks making it difficult to align the chip and substrate before joining. To align chips in the prior art process, the WLUF material either must be transparent or translucent and the thickness of the layer must be thin enough so that the solder bumps are still visible. It is desirable to have a thicker WLUF material so that less air is trapped between the underfill and substrate, but a thicker WLUF material makes the solder bumps less visible. Thus, alignment of the chip and substrate is a significant problem with a thicker WLUF material.

Accordingly, a need exists for a process to align a chip and substrate when using the WLUF process having a thick WLUF material. These and other needs are met by laser assisted wafer dicing of WLUF chips. Other advantages of the present invention will become apparent from the following description and appended claims.

### SUMMARY OF THE INVENTION

The invention is a process for aligning a chip and substrate via alignment marks which are made visible by laser assisted wafer dicing of WLUF wafers.

Other embodiments of the invention are disclosed herein.

### BRIEF DESCRIPTION OF THE DRAWINGS

FIG. 1 depicts the prior-art wafer level underfill process

FIG. 2 is a schematic of the prior-art standard wafer-dicing process: a) a bumped wafer with some dicing channels indicated; b and c) dicing of said wafer in the dicing channels; and d) the edge of two diced chips.

FIG. 3 is a schematic of the prior-art laser-assisted wafer dicing process: a) overall process; b) laser cutting through the ILD; c) dicing blade cutting through semiconductor wafer; d) the dicing channel in the ILD after the laser has passed; and e) the profile of two chip edges after dicing with the laser-assisted dicing process.

FIG. 4 is a schematic of the laser-assisted dicing process of a wafer coated with a wafer-level, over-bump applied underfill according to this invention: a) overall process; b) laser cutting through the WLUF coating and the ILD; c) dicing blade cutting through the semiconductor wafer; d) the dicing channel in the WLUF material and ILD after the laser has passed; and e) the profile of two chip edges after dicing with the laser-assisted dicing process of the current invention

FIG. 5 is a schematic of placing alignment marks near the dicing channels in accordance with this invention: a) deposition of the alignment marks directly on the semiconductor surface (two chip sites are shown throughout). Appearance of the chip sites b) after application of the WLUF material c) after removal by laser etching of the WLUF material and the ILD layers, and d) after dicing of the wafer in the laser defined dicing channels.

FIG. 6 shows a schematic of another design for alignment marks; a four corner site is shown before and after dicing. Other marks and combination of marks are possible.

FIG. 7 is a schematic of the process flow using the current invention.

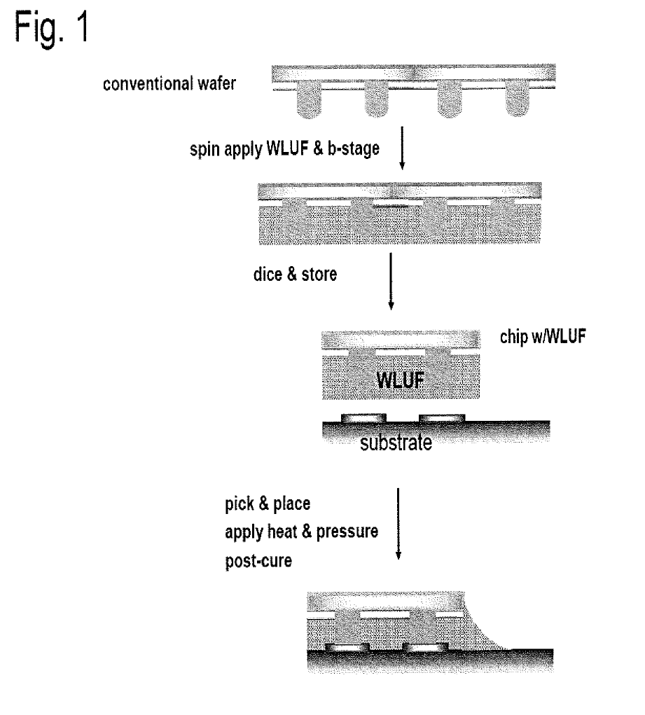

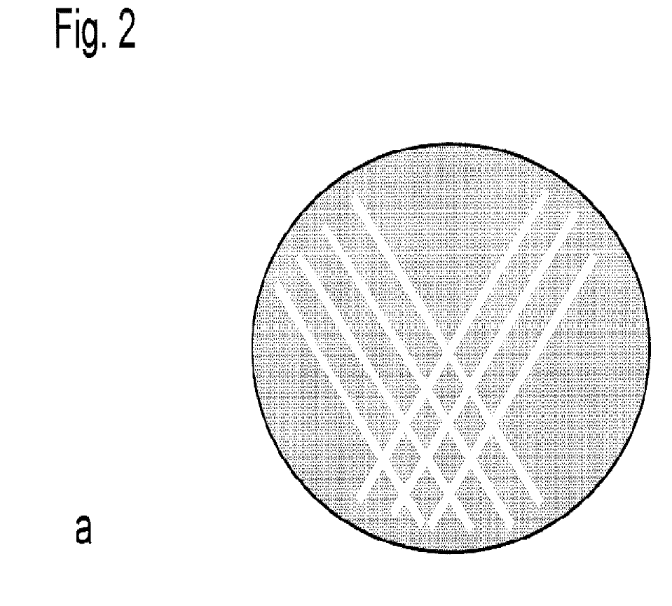

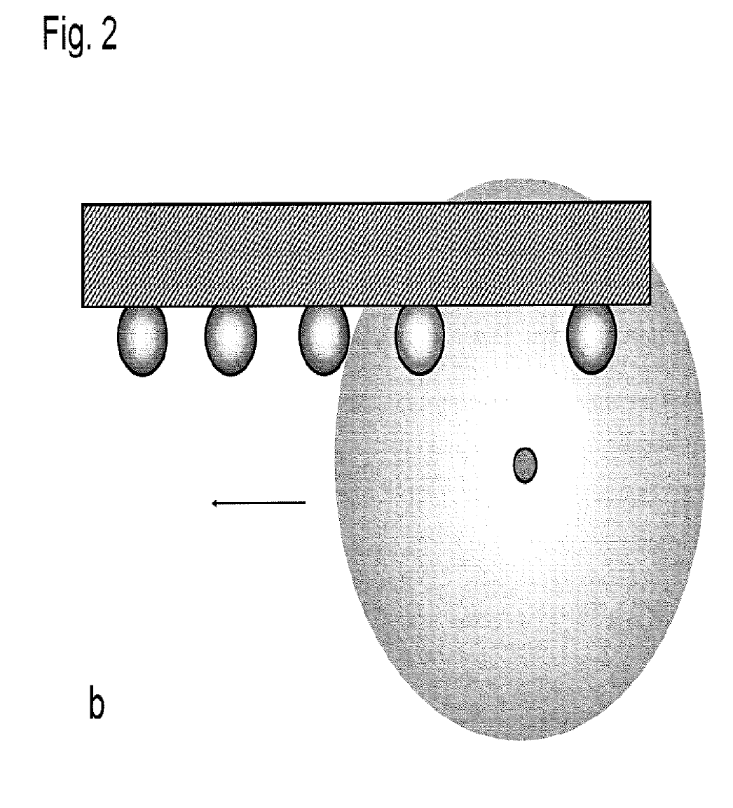

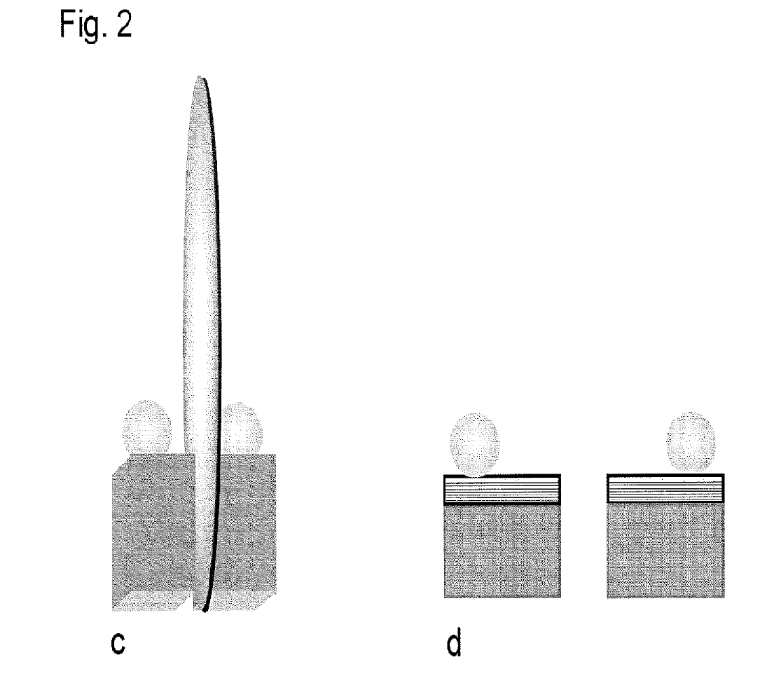

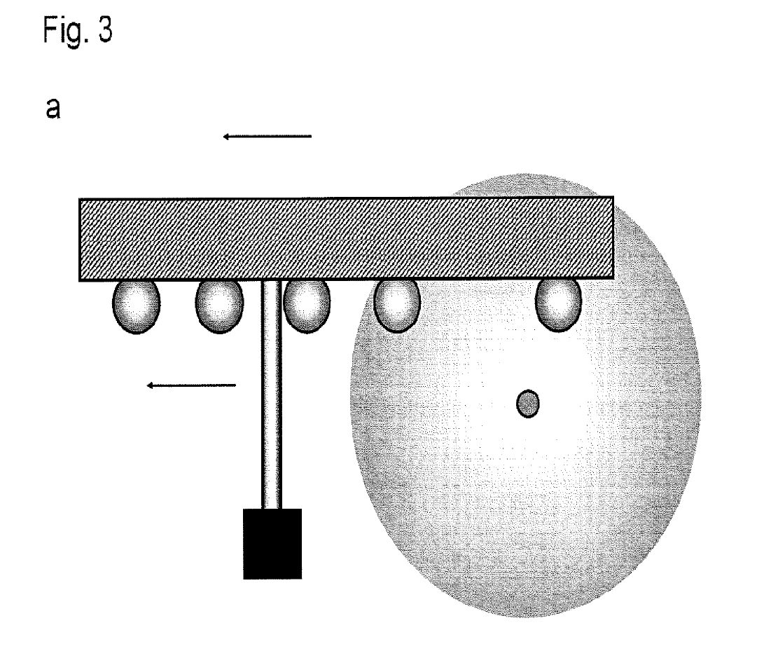

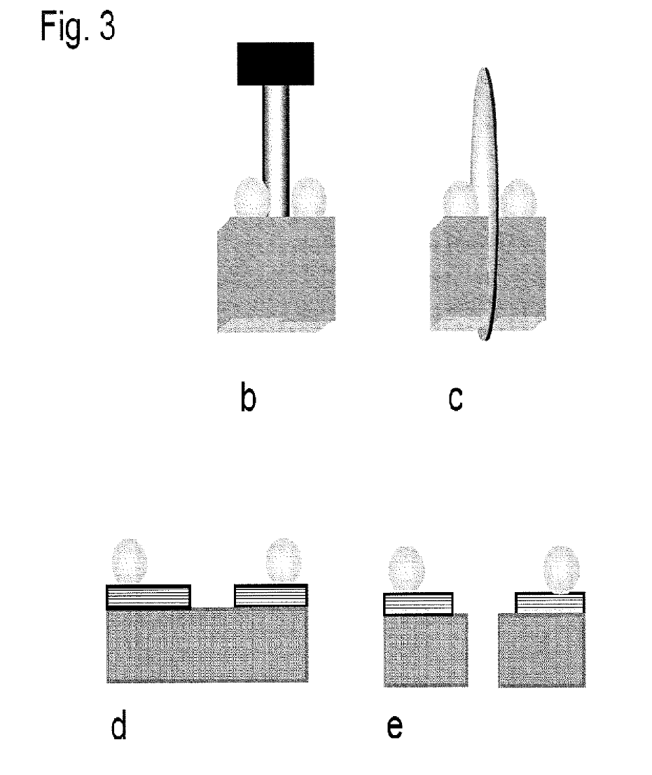

### DETAILED DESCRIPTION OF THE INVENTION

The invention is for a semiconductor wafer and the process of aligning a WLUF chip and a substrate using laser-assisted dicing of a WLUF wafer. Alignment marks are placed on the wafer near the dicing channels prior to solder bumping and completion of the back-end-of-line (BEOL) process. After such completion, the WLUF material is deposited on the wafer and b-staged. The wafer is then diced using a laser assisted dicing process which exposes the alignment marks. The chip is then joined to a substrate.

Any variety of WLUF chips may be employed including but not limited to Si wafers or SiGe wafers. The WLUF process may be any known WLUF process, such as but not limited to that disclosed in U.S. Pat. No. 6,919,420. In the prior art process, the WLUF material must be either transparent or translucent enough in the layer thickness applied over the solder bumps, so that the solder bump pattern is fully or substantially visible. This is necessary in order to align a chip obtained after wafer dicing to a substrate. In the prior art process, aligning a chip requires optically recognizing alignment marks or the solder bump pattern and using this information to align the chip to the substrate before actual chip to substrate joining.

The requirement of transparency or translucency of the WLUF material in the prior art limits its range of filler content as well as its range of layer thickness. On the other hand, it has been found that thicker WLUF layers lead to less inclusion of air during chip to substrate joining and thus is desirable. These limitations are overcome with the current invention by applying alignment marks either on top of the ILD or on top of the active front side of the semiconductor surface and using laser assisted dicing to make these marks detectable by either visual observation or by other means to detect the marks such as a pick-and-place tool or infrared, etc.

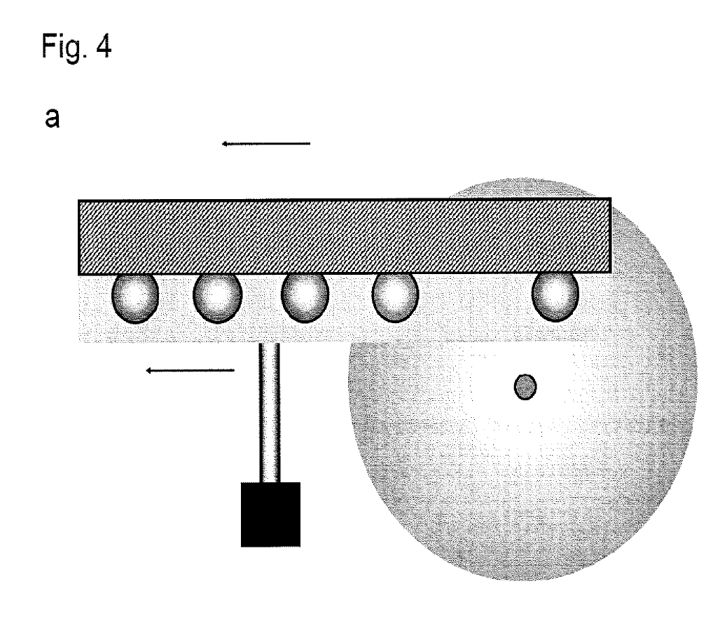

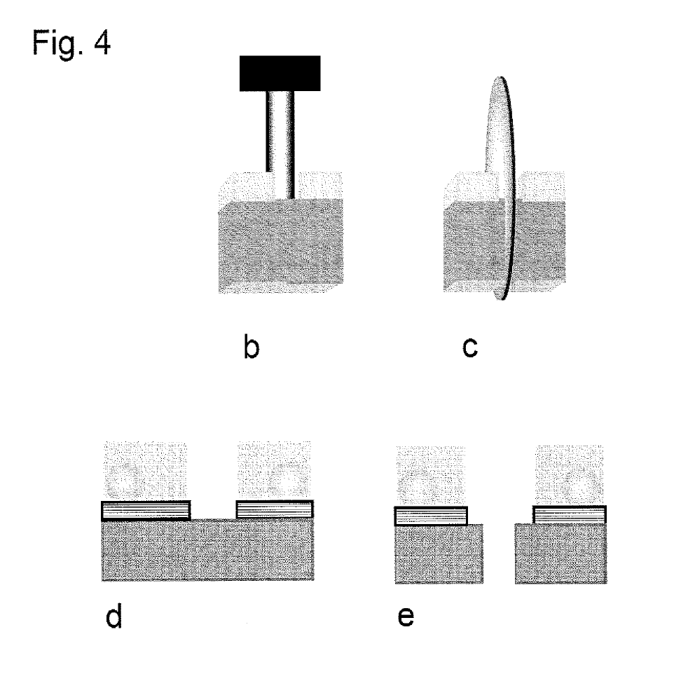

FIG. 4 is a schematic of one embodiment of the inventive laser-assisted dicing process of a wafer coated with a wafer-level, over-bump applied underfill according to this invention. FIG. 4a shows an overview of the laser-assisted dicing process. FIG. 4b shows how the WLUF and ILD layer on the wafer are first cut using a laser beam creating a dicing channel with a profile shown in FIG. 4d (laser scribing process), followed by step (c) wherein the dicing blade cuts through the semiconductor wafer in the dicing channels created by the laser in the WLUF material and ILD. The profile of two chip edges are thus shown in step (e).

The alignment marks may be deposited at any number of steps in the wafer process prior to the solder bump step, such as but not limited to during the crack stop process, at the zero level, after the ILD layer deposition, or any combination thereof. The alignment marks may consist of any variety of strips in uniform or varying width/length perpendicular to two or more of the dicing channels surrounding the chip. The alignment marks are placed in fixed relation to the bump pattern on the wafer. With the knowledge of the location of these strips on at least two sides the position, the solder bump pattern can be known exactly. While two alignment marks on two sides perpendicular to each other would be sufficient, redundent alignment marks are preferred. The alignment marks may cross the dicing channel. Other patterns, for example lines with varying distances from each other, may also be used.

Laser assisted wafer dicing uses a laser beam to cut a path into the materials on top of the semiconductor chip. The laser may be any known device such as those manufactured by Disco Corporation of Santa Clara, Calif. and/or Advanced Dicing Technologies of Horsham, Pa. The path makes visible alignment marks deposited on the wafer. To uncover the alignment marks the laser may cut through the WLUF material or the in a WLUF material and the ILD, depending on where alignment marks are placed on the wafer/chip. The path cut into these materials by the laser is always wider than the width of the dicing blade so that after dicing a small part of the semiconductor material is visible. In the present invention the alignment marks are placed in the area that will be exposed by the laser assisted wafer dicing process.

Laser ablation to make visible the alignment marks after dicing of the wafer may also be employed.

After the alignment marks are made and the BEOL process is completed, the wafer is bumped. Next the WLUF material is deposited on the wafer and b-staged. The WLUF material may be any known to those skilled in the art but with a thickness previously unavailable for the WLUF process. The thickness of the WLUF material may be about 5 to about 100 microns as measured from on top of the bump.

The wafer is then diced using a laser assisted dicing process which exposes the alignment marks. The bumps and alignment marks should thus be aligned and the chip is joined to a substrate.

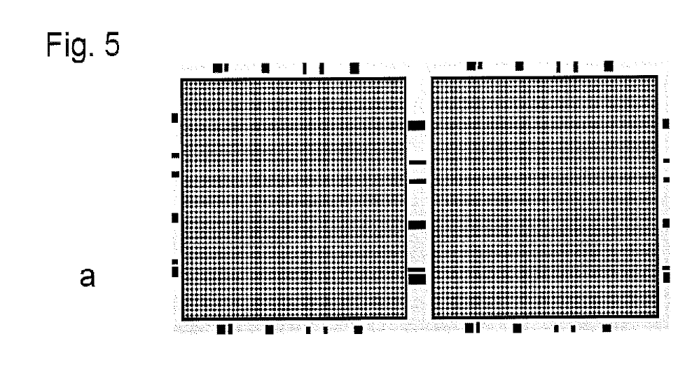

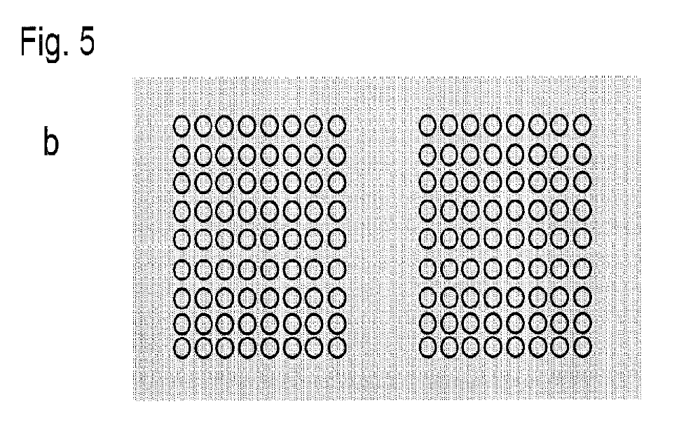

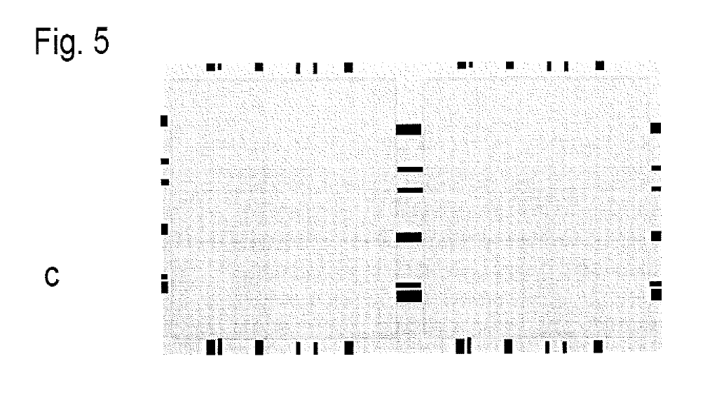

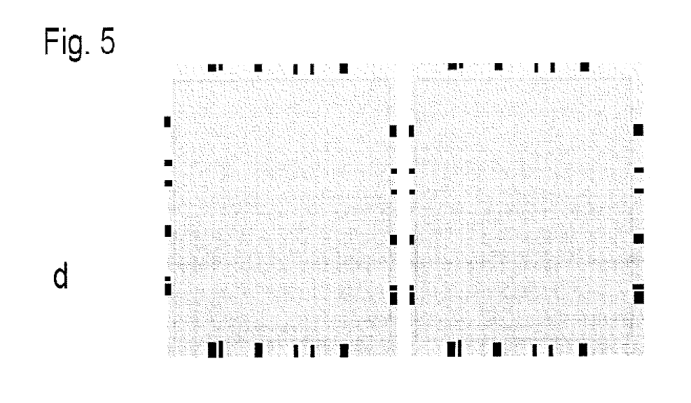

In another embodiment of the invention, as shown in FIG. 5, the alignment marks are placed near the dicing channels. The process includes but is not limited to depositing the alignment marks directly on the semiconductor surface. The alignment marks can be made visible after removal by laser etching of the WLUF material and the ILD layers, and/or after dicing of the wafer in the laser defined dicing channels.

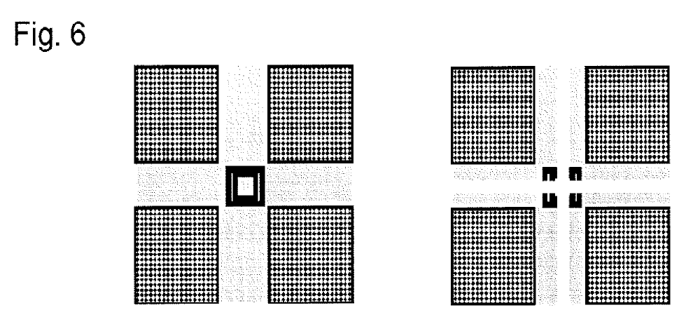

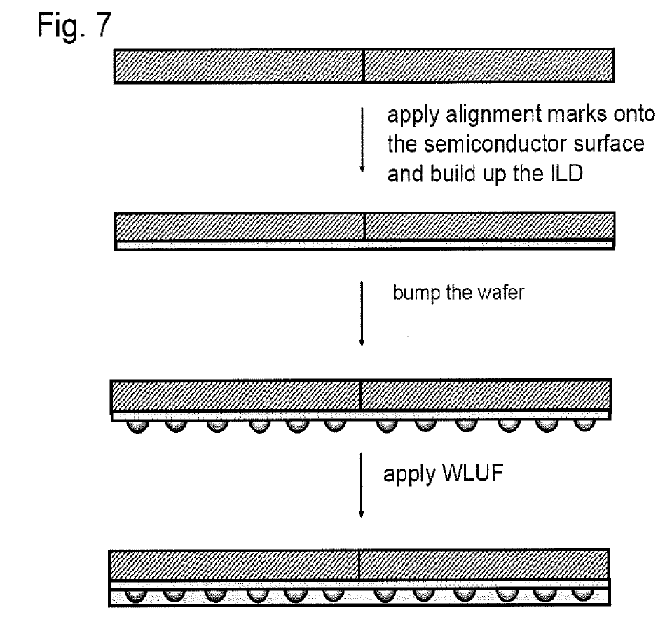

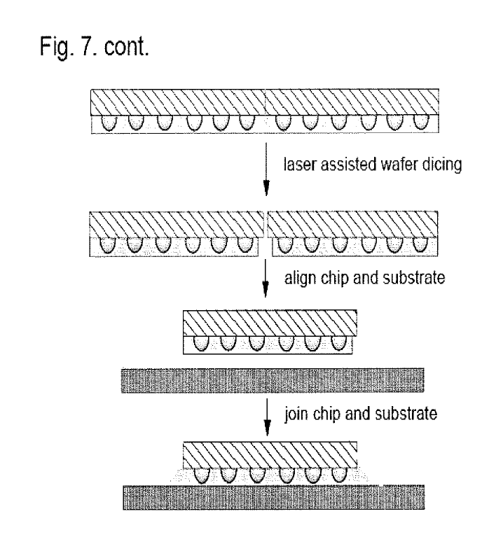

In a further embodiment of the invention the alignment marks may be made in a four corner site. FIG. 6 shows the alignment mark location before and after dicing. Other marks and combination of marks are possible.

The substrate may be any organic material including but not limited to another chip or electronic board.

The process and structure of the present invention is further illustrated by the following non-limiting examples.

### EXAMPLE 1

Three alignment marks are applied to a silicon wafer during C-level deposition. The three base alignment marks are each located on a separate chip side for all chip outlines on the wafer. The chip process is continued through solder bumping after which a WLUF material is applied in thickness above 5 microns, which material is then b-staged. The wafer is diced into separate chips with a laser. The alignment marks are detectable to facilitate alignment of each chip with a substrate.

The invention has been described in terms of preferred embodiments thereof, but is more broadly applicable as will be understood by those skilled in the art. The scope of the invention is only limited by the following claims.

1. A semiconductor wafer comprising:
(a) at least two dicing channels on the wafer;
(b) a pattern of solder bumps on the wafer; and
(c) at least two alignment marks deposited near the dicing channels wherein the alignment marks reference the location of the pattern.

2. The semiconductor wafer of claim 1 wherein the alignment marks are deposited near a multiple of the dicing channels.

3. The semiconductor wafer of claim 1 wherein the alignment marks cross the dicing channels.

4. The semiconductor wafer of claim 1 wherein the alignment marks are recognizable by visualization.

5. The semiconductor wafer of claim 1 wherein the alignment marks comprise lines of varying width.

6. The semiconductor wafer of claim 1 wherein the alignment marks comprise lines at various distance to each other.

7. The semiconductor wafer of claim 1 further comprising an interlayer dielectric connect structure via a back-end-of-line process.

8. The semiconductor wafer of claim 1 further comprising a wafer level underfill material layer on the solder bumps.

9. The semiconductor wafer of claim 8 wherein the wafer level underfill material layer is b-staged.

10. The semiconductor wafer of claim 8 wherein the wafer level underfill material layer is from about 5 microns to about 100 microns thick when measured above the solder bump.

11. The semiconductor wafer of claim 1 wherein the alignment marks are made visible through laser ablation.

12. The semiconductor wafer of claim 11 wherein the laser ablation is conducted before wafer dicing.

13. The semiconductor wafer of claim 11 wherein the laser ablation is conducted after wafer dicing.

14. The semiconductor wafer of claim 1 wherein the alignment marks outline a chip.

15. The semiconductor wafer of claim 14 wherein the alignment marks are present in sufficient quantity to align the chip with a substrate.

16. A process for aligning a substrate and a wafer level underfilled coated chip comprising:
a) depositing at least two alignment marks on a wafer having at least two dicing channels;
b) bumping the wafer such that solder bumps are created;
c) depositing a wafer level underfill material layer onto the wafer;
d) laser assisted dicing the wafer to form a chip and to expose the alignment marks;
e) aligning the alignment marks on the chip with a substrate; and
f) joining the chip to the substrate.

17. The process of claim 16 wherein the alignment marks are aligned on the wafer during the process of depositing chip crack stops.

18. The process of claim 16 wherein the wafer level underfilled material layer is b-staged.

19. The process of claim 16 wherein the water level underfill material layer is from about 5 microns to about 100 microns thick when measured above the solder bump.

20. The process of claim 16 wherein the alignment marks are aligned on the wafer during the process of depositing chip crack stops.

21. The process of claim 16 wherein the alignment marks cross the dicing channels.

22. The process of claim 16 wherein the alignment marks comprise lines of varying width.

23. The process of claim 16 wherein the alignment marks comprise lines at various distance to each other.

24. The process of claim 16 further comprising a back-end-of-line process.

25. A process for aligning a substrate and a wafer level underfill material coated chip comprising:
a) depositing at least two alignment marks on a wafer having at least two dicing channels;
b) bumping the wafer such that solder bumps are created;
c) depositing a wafer level underfilled material layer onto the wafer;
d) laser assisted dicing the wafer to form a chip;
e) laser ablation of the chip to expose the alignment marks;
f) aligning the alignment marks on the chip with a substrate; and
g) joining the chip to the substrate.

26. A semiconductor wafer comprising:
a) at least two dicing channels on the wafer;
b) a pattern of solder bumps on the wafer;
c) a wafer level underfill material layer on the solder bumps; and
d) at least three alignment marks deposited near the dicing channels wherein the alignment marks reference the location of the pattern.

27. The semiconductor wafer of claim 26 wherein the wafer level underfill material layer is b-staged.

28. The semiconductor wafer of claim 26 wherein the wafer level underfill material layer is from about 5 microns to about 100 microns thick when measured above the solder bump.

29. A semiconductor wafer comprising:
a) at least two dicing channels on the wafer;
b) a pattern of solder bumps on the wafer;
c) a b-staged wafer level underfill material layer on the solder bumps; and
d) at least three alignment marks deposited near the dicing channels wherein the alignment marks reference the location of the pattern, are uniform or varying width, and are perpendicular to at least two of the dicing channels.

30. The semiconductor wafer of claim 29 wherein the wafer level underfill material layer is from about 5 microns to about 100 microns thick when measured above the solder bump.
